(19) United States
(12) Patent Application Publication
(10) Pub. No.: US 2012/0242411 A1
(43) Pub. Date: Sep. 27, 2012

(54) OPERATIONAL AMPLIFIER

(75) Inventors: Po-Yu TSENG, Zhongli City (TW); Jin-Lin Huang, Zhubei City (TW); Keko-Chun Liang, Hsinchu City (TW)

(73) Assignee: NOVATEK MICROELECTRONICS CORP., Hsinchu (TW)

(21) Appl. No.: 13/428,456

(22) Filed: Mar. 23, 2012

(30) Foreign Application Priority Data
Mar. 24, 2011 (TW) 100110197

(51) Int. Cl. H03F 3/04; H03F 3/68

(52) U.S. Cl. 330/296; 330/124 R

(57) ABSTRACT

An operational amplifier providing an output voltage signal to drive a load in response to an input voltage signal is provided. The operational amplifier includes a first input stage and a second input stage, a second stage and an output enable switch. The first input stage provides a first intermediate signal according to the voltages of an input and an output voltage signals in a transitional state. The second input stage provides a second intermediate signal according to the input and the output voltage signals in a steady state. The second stage provides the output voltage signal to an output node according to the first and the second intermediate signals in the transitional and the steady states respectively. The output enable switch is enabled in an output enable period to drive the load with the output voltage signal.

This application claims the benefit of Taiwan application Serial No. 100110197, filed Mar. 24, 2011, the subject matter of which is incorporated herein by reference.

### BACKGROUND OF THE INVENTION

1. Field of the Invention

The invention relates in general to an operational amplifier, and more particularly to an operational amplifier capable of avoiding reliability problem.

2. Description of the Related Art

Of the current technologies, the operational amplifier is often used as a voltage buffer to drive the voltage of the load circuit connected thereto. In general, the voltage buffer includes a differential input transistor circuit and a gain stage, which respectively amplify an input signal and an output signal to obtain a first amplification signal and perform gain amplification according to the first amplification signal to obtain an output signal. In general, the level of the output signal follows the level of the input signal.

However, in practical operation, due to different performances in driving the current and the differences in the magnitudes of the loads, the level switching rates of the input signal and the output signal cannot be synchronized. In the long run, the non-synchronization in level switching rate will incur different degrees of degeneration of element characteristics to the transistors of the differential input transistor circuit, and further increase offset voltage and decrease reliability and lifespan for the operational amplifier.

### SUMMARY OF THE INVENTION

The invention is directed to an operational amplifier. In comparison to conventional operational amplifier, the relevant operational amplifier of the present invention has the advantages of effectively avoiding inconsistent degeneration of element characteristics occurring to the differential input and further suppressing offset voltage and increasing reliability and lifespan for the operational amplifier.

According to a first aspect of the present invention, an operational amplifier providing an output voltage signal to drive a load in response to an input voltage signal is provided. The operational amplifier includes a first input stage, a second input stage, an output node, a second stage and an output enable switch. The first input stage is enabled in a transitional period corresponding to the input and the output voltage signals in response to the first pulse signal to provide a first intermediate signal according to the input and the output voltage signals in a transitional state. The second input stage is enabled in a steady period corresponding to the input and the output voltage signals in response to the second pulse signal to provide a second intermediate signal according to the input and the output voltage signals in a steady state. The second stage is coupled to the output node, and provides the output voltage signal to the output node according to the first and the second intermediate signal in the transitional and the steady periods respectively. The output enable switch is coupled between the output node and the load, and is enabled in an output enable period to drive the load with the output voltage signal in response to the third pulse signal.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a block diagram of an operational amplifier according to an embodiment of the present invention;

FIG. 2 shows a detailed circuit diagram of the input stage 12 of FIG. 1;

FIG. 3 shows a detailed circuit diagram of the input stage 14 of FIG. 1;

FIG. 4 shows a relevant signal timing diagram of the operational amplifier 1 of FIG. 1;

FIG. 5 shows another detailed circuit diagram of the input stage 12 of FIG. 1;

FIG. 6 shows further another detailed circuit diagram of the input stage 12 of FIG. 1;

FIG. 7 shows further another detailed circuit diagram of the input stage 12 of FIG. 1;

FIG. 8 shows another detailed circuit diagram of the input stage 14 of FIG. 1;

FIG. 9 shows further another detailed circuit diagram of the input stage 14 of FIG. 1.

### DETAILED DESCRIPTION OF THE INVENTION

The operational amplifier of the embodiment of the invention selectively amplifies an input signal and an output signal with different input stage circuits when the input signal or the output signal is in a transitional state or a steady state.

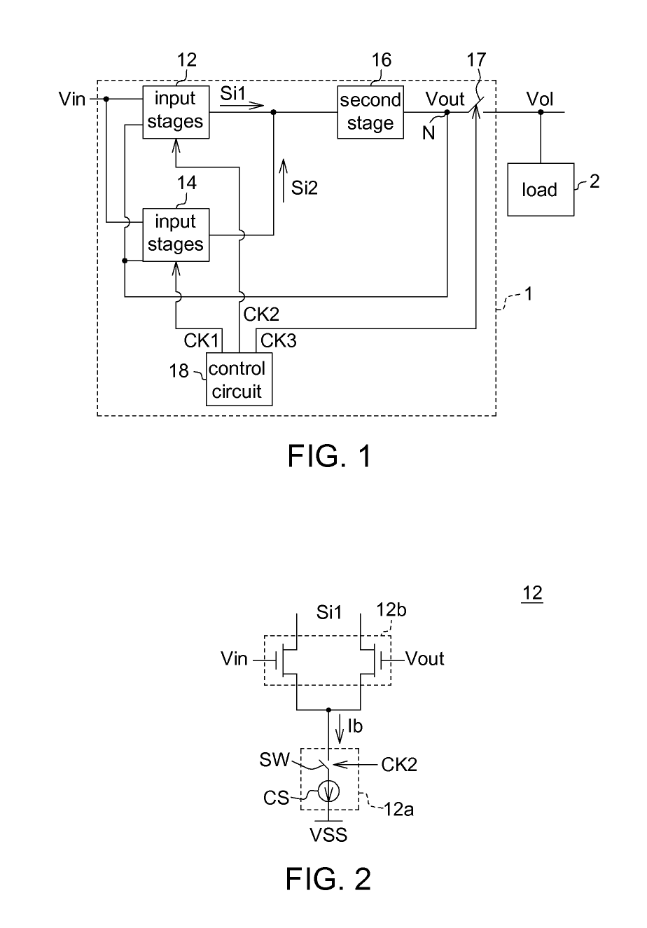

Referring to FIG. 1, a block diagram of an operational amplifier according to an embodiment of the present invention is shown. The operational amplifier 1 provides an output voltage signal Vout to drive a load 2 in response to an input voltage signal Vin. The operational amplifier 1 includes input stages 12 and 14, an output node N, a second stage 16 and an output enable switch 17.

The input stage 12 is enabled in a transitional period TPt, corresponding to the input and the output voltage signals Vin and Vout, in response to a pulse signal CK2 to provide an intermediate signal Vi1 according to the input and the output voltage signals Vin and Vout in a transitional state. Referring to FIG. 2, a detailed circuit diagram of the input stage 12 of FIG. 1 is shown. The input stage 12, for example, includes a current path switch unit 12a and a differential input transistor circuit 12b. The current path switch unit 12a provides a bias current signal Ib in a transitional period in response to the pulse signal CK2. For example, the current path switch unit 12a includes a switch SW and a current source CS. The differential input transistor circuit 12b is enabled in response to the bias current signal Ib to amplify the input and the output voltage signals Vin and Vout and accordingly provide a first intermediate signal Si1. For example, the differential input transistor circuit 12b is implemented with N-type metal oxide semiconductor (MOS) transistors.

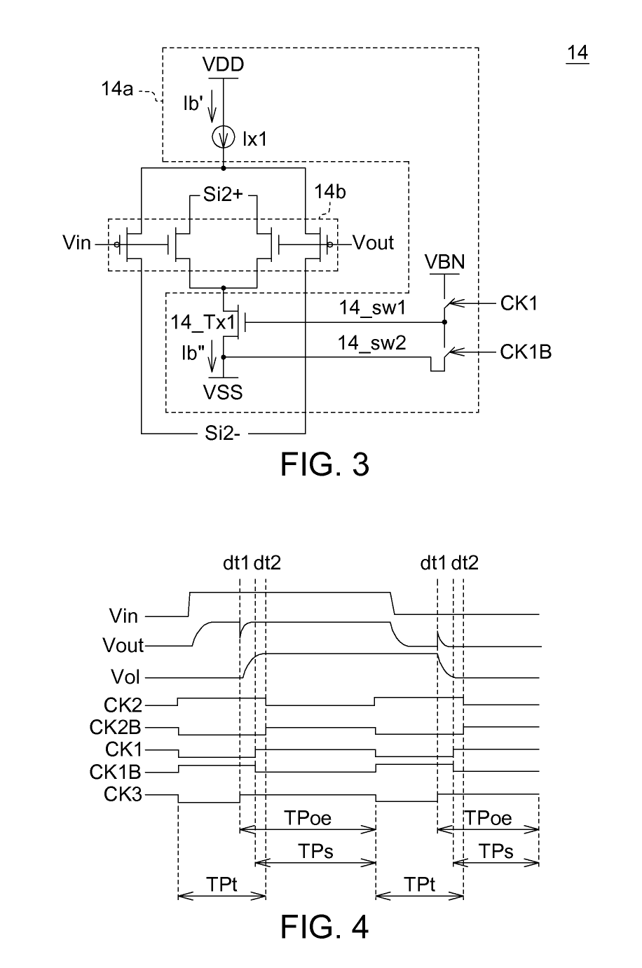

The input stage 14 is enabled in a steady period TPs corresponding to the input and the output voltage signals Vin and Vout in response to the pulse signal CK1 to provide an intermediate signal Vi2 according to the input and the output voltage signals Vin and Vout in a steady voltage. Referring to FIG. 3, a detailed circuit diagram of the input stage 14 of FIG. 1 is shown. The input stage 14, for example, includes a current path switch unit 14a and a differential input transistor circuit 14b. The current path switch unit 14a provides bias current signals Ib′ and Ib″ in a steady period TPs in response to the pulse signal CK1. For example, the current path switch unit 14a includes a current source Ix, a transistor 14_Tx1, and switches 14_sw1 and 14_sw2. The current source Ix provides a current signal Ib′. The switch 14_sw1 is turned on to provide a high level reference voltage signal VBN to the gate of the transistor 14_Tx1 in response to the enabled pulse signal CK1. The switch 14_sw2 is turned on in response to the enabled inverse pulse signal CK1B, i.e. the inverse signal of the pulse signal CK1, to provide a power voltage signal VSS to the gate of the transistor 14_Tx1.

The transistor 14_Tx1, for example, is implemented with an N-type MOS transistor, wherein when the pulse signal CK1 is not enabled while the inverse pulse signal CK1B, i.e. the inverse signal of the pulse signal CK1, is enabled, the gate of the transistor 14_Tx1 receives the power voltage signal VSS and the transistor 14_Tx1 is correspondingly turned off. When the pulse signal CK1 is enabled while the inverse pulse signal CK1B is not enabled, the gate of the transistor 14_Tx1 receives the high level reference voltage signal VBN and the transistor 14_Tx1 is correspondingly turned on to provide the bias current signal Ib″.

The differential input transistor circuit 14b is enabled in response to the bias current signals Ib′ and Ib″ to amplify the input and the output voltage signals Vin and Vout and accordingly provide an intermediate signal Si2. For example, the intermediate signal Si1 includes signal components Si2+ and Si2−.

The second stage 16 is coupled to the output node N. The second stage 16 provides the output voltage signal Vout to the output node N according to intermediate signal Si1 in a transitional period TPt, and provides the output voltage signal Vout to the output node N according to intermediate signal Si2 in a steady period TPs. For example, the second stage 16 includes a gain stage circuit and an output stage circuit (not illustrated) of the operational amplifier 1.

The output enable switch 17 is coupled between the output node N and the load 2. The output enable switch 17 is enabled in an output enable period TPoe in response to the pulse signal CK3 to drive a load 2 with the voltage driving signal Vol according to the output voltage signal Vout.

For example, the operational amplifier 1 further includes a control circuit 18, which respectively provides pulse signals CK1-CK3 to control the switching operations of the input stages 12 and 14 and the output enable switch 17.

Referring to FIG. 4, a relevant signal timing diagram of the operational amplifier 1 of FIG. 1 is shown. For example, the transitional period TPt and the steady period TPs are partly overlapped with each other in a sub-period dt2, in which the timing signals CK1 and CK2 both correspond to an enable level, e.g. high signal level, to accordingly have the input stages 12 and 14 enabled at the same time. Thus, the input stages 12 and 14 are prevented from being disabled or critically enabled at the same time, and accordingly preventing error level of the voltage driving signal Vol from taking place.

However, the above implementation is merely a preferred embodiment of the present invention, and is not for limiting the present invention. For example, despite the situation that the transitional period and the steady period are not overlapped with each other may cause temporary error to the level of the voltage driving signal Vol, the non-overlapping situation still can be used in practical application. In other words, the operations of the operational amplifier of the present invention will not be affected regardless the transitional period and the steady period being overlapped or aligned with each other or not.

For example, the transitional period TPt further includes a sub-period Tp1, being between the rising edges of the timing signals CK3 and CK1, i.e. between the start time of the output enable period TPoe and the start time of the steady period TPs. Since the output enable switch 17 is turned on in the output enable period TPoe in response to the timing signal CK3 to update the level of the voltage driving signal Vol according to the output voltage signal Vout, voltage offset of the output voltage signal Vout will take place and accordingly have the level of the output voltage signal Vout deviated from the level of the input voltage signal Vin in a period from the start time of the output enable period TPoe. In the practical operations illustrated in FIG. 4, the input stage 14 remains turned off until the output enable switch 17 has been turned on for a sub-period Tp1, to accordingly avoid the occurrence of level offset of the output voltage signal Vout, which may cause degeneration of element characteristics to the input transistors of the input stage 14.

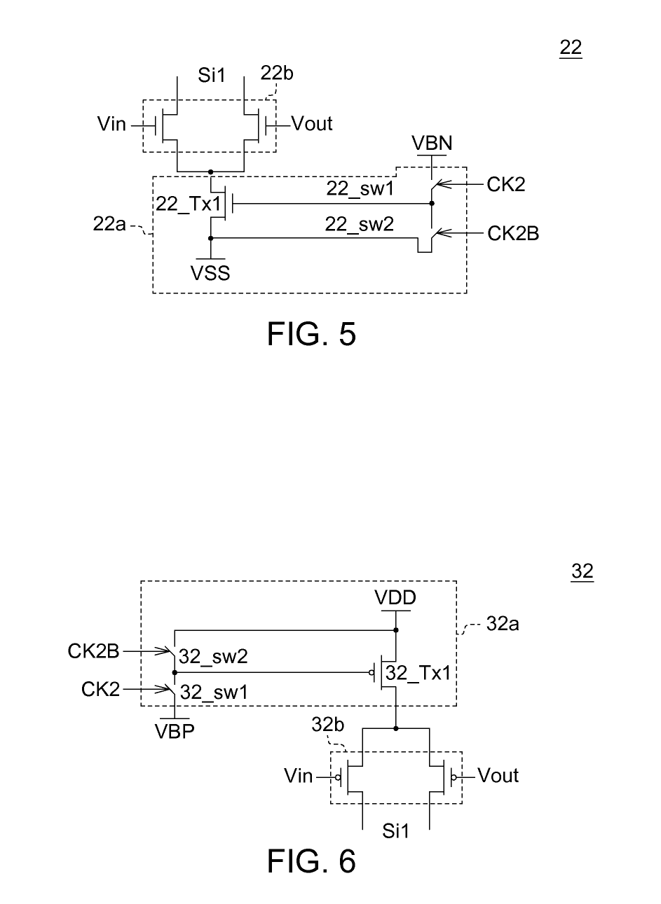

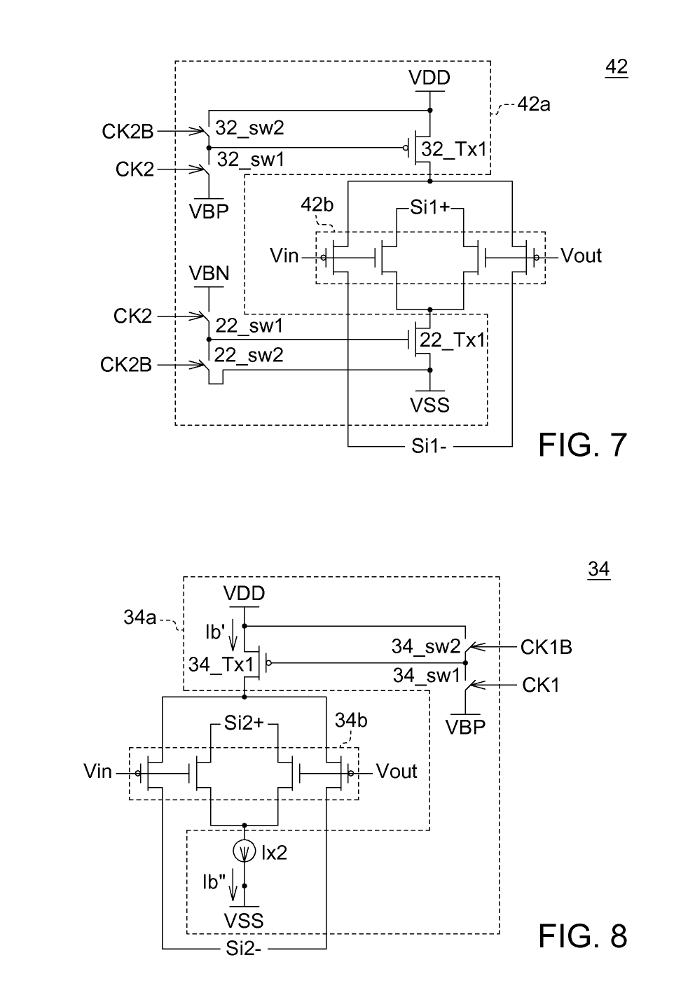

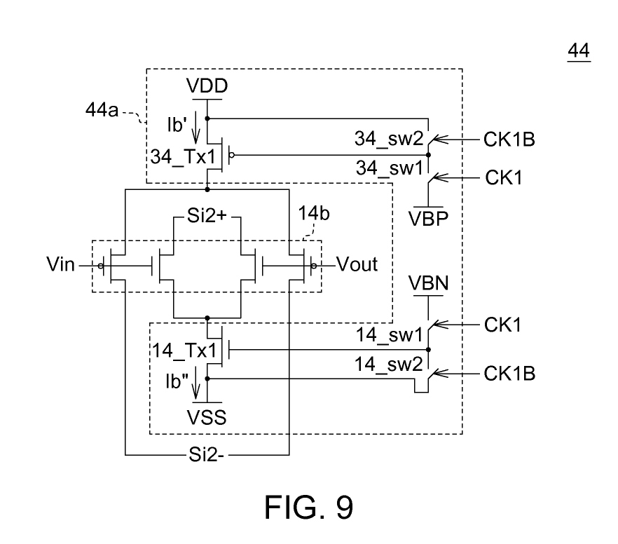

Referring to FIG. 5, another detailed circuit diagram of the input stage 12 of FIG. 1 is shown. In other examples, the current path switch unit 22a can be implemented with a transistor 22_Tx1, and switches 22_sw1 and 22_sw2, wherein the transistor 22_Tx1 is, for example, an N-type MOS transistor. Referring to FIG. 6 and FIG. 7, alternate detailed circuit diagrams of the input stage 12 of FIG. 1 are shown. In other examples, the current path switch units 32a and 42a and the differential input transistor circuits 32b and 42b of the input stage 12 can also be implemented with a P-type MOS transistor or by P-type and N-type MOS transistors. When the input stage 12 has the circuit structures illustrated in FIG. 6 and FIG. 7 respectively, the input stage 14 correspondingly has the circuit structures as illustrated in FIG. 8 and FIG. 9 respectively.

The operational amplifier of an embodiment of the invention is implemented with a first input stage and a second input stage respectively amplifying the input and the output voltage signals when the input voltage signal or the output voltage signal is in a transitional state and respectively amplifying the input and the output voltage signals when the input voltage signal or the output voltage signal is in a steady. Thus, compared with the conventional operational amplifier, the operational amplifier of an embodiment of the invention has the advantages of effectively avoiding inconsistent degeneration of element characteristics occurring to the differential input and further suppressing offset voltage and increasing reliability and lifespan for the operational amplifier.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An operational amplifier providing an output voltage signal to drive a load in response to an input voltage signal, wherein the operational amplifier comprises:
a first input stage enabled in a transitional period corresponding to the input and the output voltage signals in response to a first pulse signal to provide a first intermediate signal according to the input and the output voltage signals in a transitional state;
a second input stage enabled in a steady period corresponding to the input and the output voltage signals in response to a second pulse signal to provide a second intermediate signal according to the input and the output voltage signals in a steady state;
an output node;
a second stage coupled to the output node to provide the output voltage signal to an output node according to the first and the second intermediate signals in the transitional period and the steady period respectively; and
an output enable switch coupled between the output node and the load, and enabled in an output enable period in response to a third pulse signal to drive the load with the output voltage signal.

2. The operational amplifier according to claim 1, wherein the first input stage comprises:
a current path switch unit providing a bias current signal in the transitional period in response to the first pulse signal; and
a differential input transistor circuit enabled in response to the bias current signal to amplify the input and the output signals and accordingly provide the first intermediate signal.

3. The operational amplifier according to claim 2, wherein the differential input transistor circuit includes N-type metal oxide semiconductor (MOS) transistors.

4. The operational amplifier according to claim 2, wherein the differential input transistor circuit includes P-type MOS transistors.

5. The operational amplifier according to claim 1, wherein the second input stage comprises:
a current path switch unit providing a bias current signal in the steady period in response to the second pulse signal; and
a differential input transistor circuit enabled in response to the bias current signal to amplify the input and the output signals and accordingly provide the second intermediate signal.

6. The operational amplifier according to claim 5, wherein the differential input transistor circuit includes N-type MOS transistors.

7. The operational amplifier according to claim 5, wherein the differential input transistor circuit includes P-type MOS transistors.

8. The operational amplifier according to claim 1, wherein the output enable period has a start time which falls within the transitional period.

9. The operational amplifier according to claim 1, wherein the transitional period and the steady period are partly overlapped with each other.

10. The operational amplifier according to claim 1, further comprising:
a control circuit providing the first to the third pulse signals to perform timing control on the operational amplifier.
